(19) United States
(12) Patent Application Publication
(10) Pub. No.: US 2024/0311522 A1
(43) Pub. Date: Sep. 19, 2024

(54) A COMPUTER-AIDED DESIGN COST CALCULATION SYSTEM

(71) Applicant: POOL SITE QUOTE PTY LTD, Seaforth (AU)

(72) Inventor: Julian BRADY, Seaforth (AU)

(21) Appl. No.: 18/251,455

(22) PCT Filed: Nov. 10, 2021
(86) PCT No.: PCT/AU2021/051327

§ 371 Date: May 2, 2023

(30) Foreign Application Priority Data
Nov. 11, 2020 (AU) 2020904120

(51) Int. Cl. G06F 30/13

(52) U.S. Cl. CPC G06F 30/13

(57) ABSTRACT

A pool quotation cost calculation system employs interactive graphical user interface configuration controls for rapid configuration of relatively accurate on-screen pool perimeter and depth profile geometry for many types of pool configurations suitable for making of relatively accurate cost calculations dynamically in substantial real-time using pre-configured size, area and/or volumetric dependent cost calculation parameters.

### FIELD OF THE INVENTION

This invention relates generally to computer-aided design and, more particularly, to a pool quotation cost calculation system which employs interactive graphical user interface configuration controls for rapid configuration of relatively accurate on-screen pool perimeter and depth profile geometry for many types of pool configurations.

### SUMMARY OF THE DISCLOSURE

The present pool quotation cost calculation system employs interactive graphical user interface configuration controls for rapid configuration of relatively accurate on-screen configuration of pool perimeter and depth profile geometry for many types of pool configurations.

Perimeter and the depth profiles configured on-screen in this way are then used by a cost calculation controller for dynamic cost calculation in accordance with preconfigured size, area and/or volumetric depended cost calculation parameters which may be displayed on screen in real time and used to populate data fields of electronic documents for instantaneous download.

The configuration controls comprise an interactive perimeter profile configuration control comprises vertex controls interactively positionable on-screen to define a perimeter of a pool by rays between the vertex control. By adjusting the position of the vertex controls, pool perimeters may be drawn relatively accurately. Additional vertex controls may be inserted to bisect rays to allow for perimeter definition of any shape, size and/or complexity.

The configuration controls further comprise an interactive depth profile configuration control interactively controllable on-screen to define a depth profile of the pool.

The interactive depth profile configuration control may display a vertical cross-section of the pool and comprise a plurality of marker controls interactively positionable on-screen thereon. The vertical positioning of each marker defines the depth profile. The depth profile may be interpolated using curved line interpolation between the markers.

These on-screen controls allow for the rapid and relatively accurate computer-aided design of pool perimeter and a depth profile geometry suitable for making of relatively accurate cost calculations dynamically in substantial real-time.

Other aspects of the invention are also disclosed.

### BRIEF DESCRIPTION OF THE DRAWINGS

Notwithstanding any other forms which may fall within the scope of the present invention, preferred embodiments of the disclosure will now be described, by way of example only, with reference to the accompanying drawings in which:

FIG. 1 shows a computer-aided design cost calculation system in accordance with an embodiment;

FIG. 2 illustrates an interactive perimeter profile configuration control in accordance with an embodiment;

FIG. 3 illustrates an interactive depth profile configuration control in accordance with an embodiment;

FIG. 4 illustrates graphical user interface inputs for preconfigured size, area and/or volumetric dependent cost calculation parameters in accordance with an embodiment;

FIG. 5 illustrates a process implemented by the system of FIG. 1 for cost calculation;

FIG. 6 illustrates size, area and/or volumetric calculations made by the system of FIG. 1;

FIG. 7 shows the graphical user inputs of FIG. 7 in further detail; and

FIG. 8 illustrates exemplary processing of an electronic document generation controller in accordance with an embodiment.

### DESCRIPTION OF EMBODIMENTS

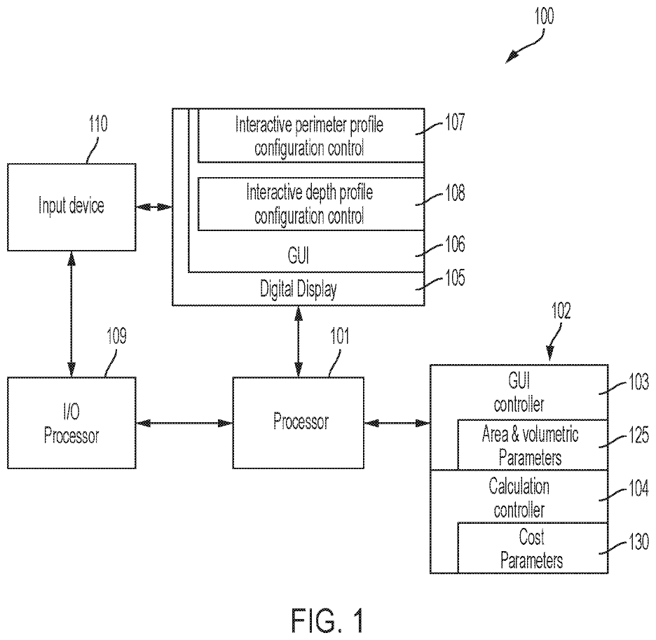

FIG. 1 shows a computer system 100 comprising a processor 101 for processing digital data. In operable communication with the processor 101 via a system bus is a memory device 102. The memory device 102 is configured for storing digital data including computer program code instructions. In use, the processor 101 fetches these computer program code instructions and associated data from the memory device 102 for interpretation and execution of the functionality described herein.

The computer program code instructions may be logically divided into a plurality of computer program code instruction controllers. As is shown, the computer system 100 may comprise a GUI controller 103 and a calculation controller 104.

The processor 101 may be in operable communication with a digital display device 105. The GUI controller 103 may cause the digital display 105 to display a graphical user interface 106 thereon. The graphical user interface 106 comprises an interactive perimeter profile configuration control 107 and an interactive depth profile configuration control 108.

The system 100 may comprise an I/O processor 109 for interfacing with various computer peripherals, including an input device 110 (such as a computer mouse or touchscreen overlay) for on-screen interaction with the graphical user interface 106.

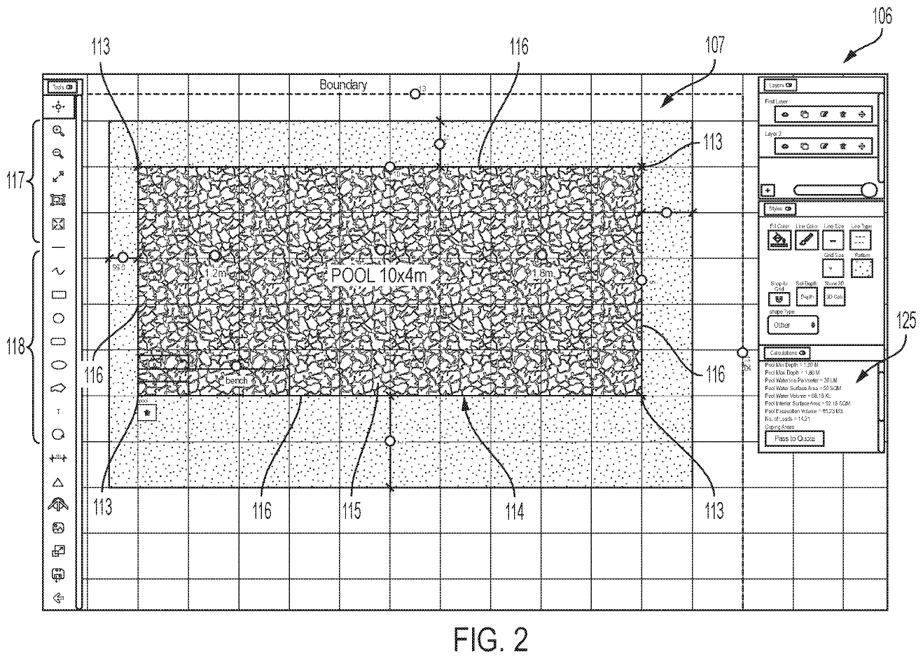

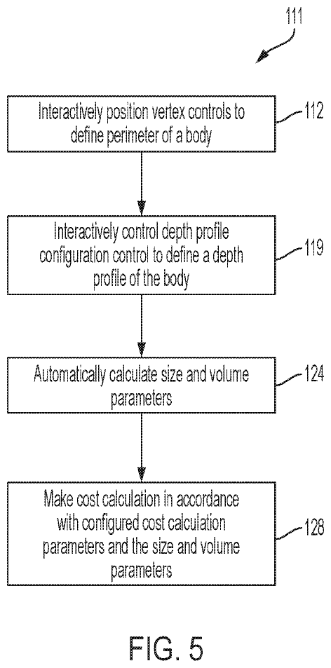

FIG. 5 shows a process 111 for automatic cost calculations implemented by the system 100 in accordance with an embodiment which will be described specifically with reference for automatic calculation of pool and spa costs which will be described with reference to accompanying FIGS. 2-4.

The process 100 comprises interactively positioning vertex controls to define a perimeter of a pool at step 112.

In this regard, FIG. 2 shows the graphical user interface 106 comprising the interactive perimeter profile configuration control 107.

The control 107 may define a grid comprising a plurality of vertex controls 113 interactively positionable on-screen to define a perimeter 114 of a pool 115 by rays 116 extend between the vertex controls 113.

The GUI 106 may comprise a plurality of view controls 117 to control at least one of position and zoom of the view of the perimeter profile configuration control 107. The GUI 106 may further comprise a plurality of shape and/or texture controls 118 to place and edit shape and/or textures displayed by the controller 107.

The controller 107 may comprise a control for adding further vertex controls 113 and/or removing vertex controls 113. In this regard, a perimeter of any shape and/or complexity may be configured using the control 107.

In the embodiment shown, the vertex controls 113 define a rectangular perimeter of a pool pool of 10×4 m.

The process 111 further comprises interactively controlling a depth profile configuration control 108 to define a depth profile of the pool at step 119.

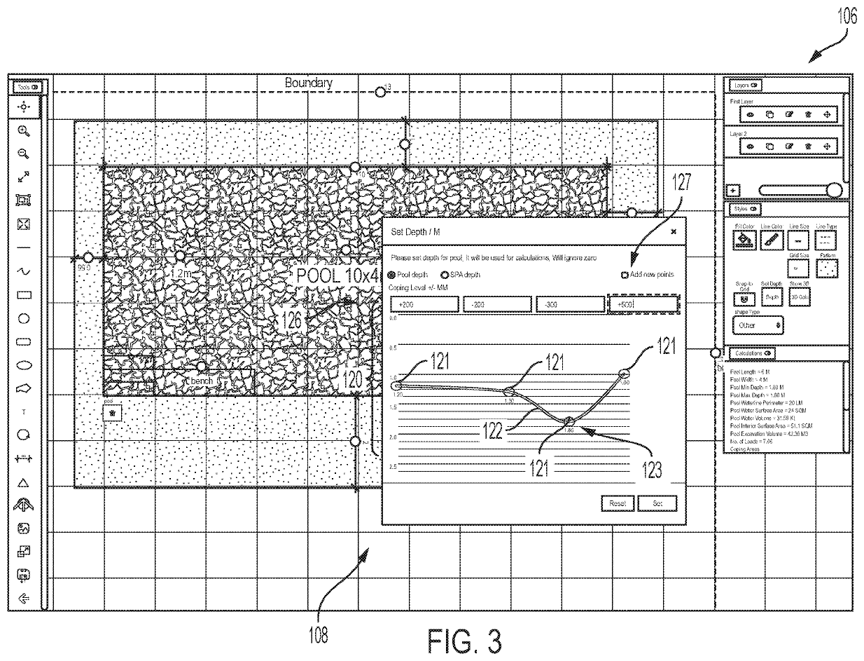

FIG. 3 shows the graphical user interface 106 comprising the interactive depth profile configuration control 108 displaying a vertical cross section 120 of the pool comprising a plurality of marker controls 121 interactively positionable on-screen and the cross-section 120. The vertical position of each marker 121 defines a depth profile 122.

The system 100 may determine the length of the pool according to the configured perimeter and configure the length of the cross-section 120 accordingly.

The depth profile 122 may comprise a curved line interpolation between the markers 121.

Each marker 121 may display a respective depth 123 adjacently which dynamically updates depending on the vertical position of the marker 121 with respect to the cross-section 120.

The interface 106 may comprise input controls configuring the maximum depth of the pool wherein the depth of the cross-section dynamically adjusts.

The depth profile configuration control 108 may comprise a control 127 to add additional markers 121. The controller 108 may further comprise a control to remove markers.

As such, a depth profile 122 of potentially any configuration may be configured using the control 108.

At step 124 of the process 111, the system 100 automatically calculates size, area and/or volumetric parameters in accordance with the parameter and depth profile configured on-screen.

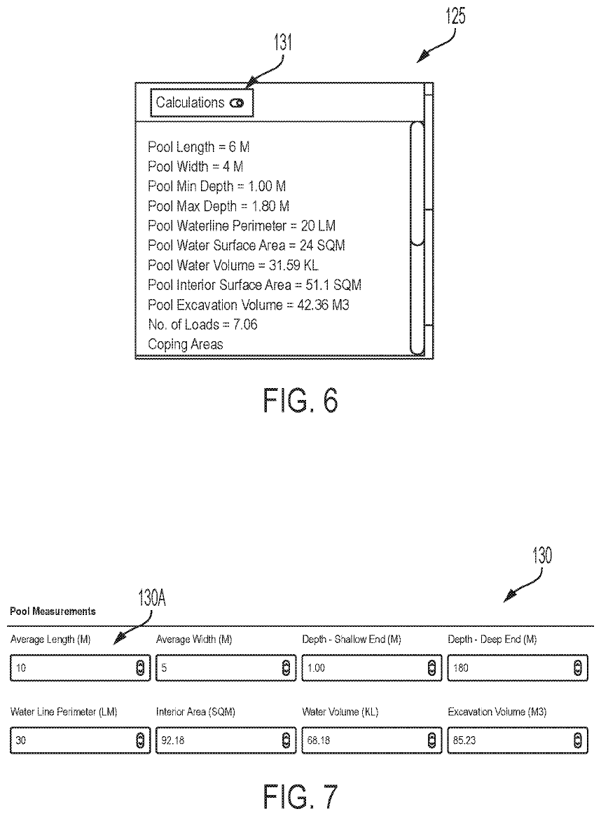

With reference to FIG. 2, there is shown the graphical user interface 106 comprising the size, area and/or volumetric parameters 125 show more detail in FIG. 6.

As is shown, the system 100 may automatically calculate at least one of length, width, minimum depth, maximum depth, perimeter length, surface area, volume, interior surface area.

The system 100 may calculate volume by summing the product of a perimeter profile width and depth at intervals along the length of the depth profile 122. Preferably, the intervals are small so as to increase the accuracy of the volume calculation, especially where the depth profile 122 is interpolated between the markers 121.

In embodiments, the interactive depth profile configuration control 108 may allow for configuration of orthogonal depth profiles so that, for example, a depth profile 122 may be specified both across the length (lengthwise depth profile 122) and width (widthwise depth profile 122) of the pool.

In accordance with this embodiment, the system 100 may calculate volume by summing depths of square intervals along both of the widthwise and lengthwise depth profiles 122.

Specifically for pools and spas, the parameters 125 calculated may include an excavation volume and the number of required loads therefor.

Furthermore, the system 100 may calculate coping areas calculated in accordance with coping area parameters 126 configured as is illustrated in FIG. 3.

As shown in FIG. 6, the interface 106 may comprise a calculation toggle control 131 which may be set to control whether the system 100 calculates the parameters 125 dynamically in real-time as the perimeter and depth profile configured on-screen.

At step 128 of process 111, the system 100 makes cost calculations in accordance with pre-configured size, area and/or volumetric dependent cost calculation parameters and the size, area and/or volumetric parameters 125.

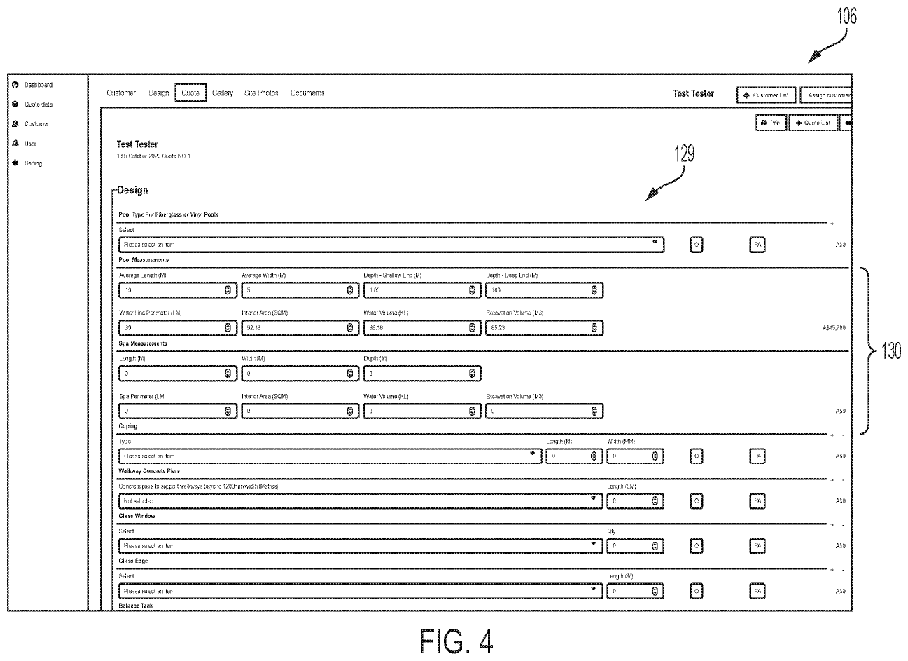

As regard, FIG. 4 shows the graphical user interface 106 comprising a cost calculation parameter control 129 wherein various cost calculation parameters may be input. The controller 129 comprises pre-configured size, area and/or volumetric dependent cost calculation parameters 130 which, in the example given comprises parameters for a pool or a spa.

The pre-configured size, area and/or volumetric dependent cost calculation parameters 130 for a pool are shown in more detail in FIG. 7.

As is shown in FIG. 7, the parameters 130 may comprise cost inputs accepting cost according to length, width, shallow and depth, deep and a depth, waterline perimeter, interior area, water volume and excavation volume. For example, for the length cost calculation input 130A, the calculation controller 104 may calculate a cost of $10 per metre of length.

Having calculated a cost using the calculated parameters 125 and the size and the pre-configured size, area and/or volumetric dependent cost calculation parameters 130, the calculation controller 104 may output a cost calculation quotation in electronic document format

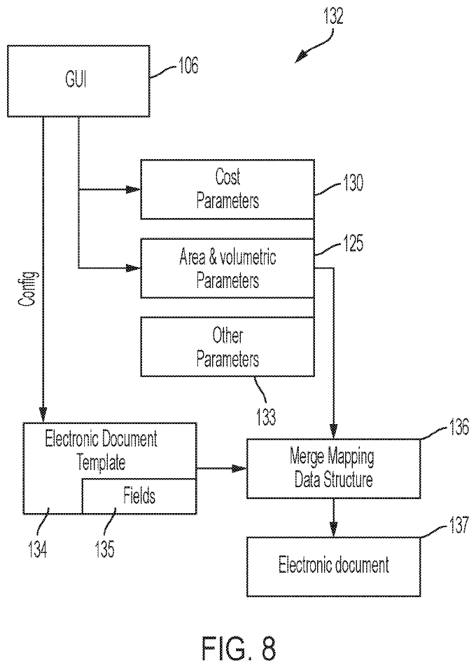

With reference to FIG. 8, in embodiments the controllers comprise an electronic document generation controller which generates electronic documents 137 using a merge mapping data structure 136.

Specifically, as the user interacts with the vertex controls 113 of the interactive perimeter profile configuration control 107 and the depth markers 121 of the interactive depth profile configuration control 108 on-screen, the system 100 dynamically generates the area and volumetric parameters 137 and the cost calculation controller 104 dynamically generates the cost parameters 130 in accordance with the pre-configured size, area and/or volumetric dependent cost calculation parameters and the perimeter and the depth profiles configured on-screen.

The merge mapping data structure 136 may comprise a markup (such as XML) or object notation (such as JSON) data structure which maps the cost parameters 130 and area and volumetric parameters 137 onto a plurality of fields 135 of an electronic document template 134.

The fields 137 of an electronic document template 134 may be configured via the user interface 106 as shown by a user having administrator access.

Specifically, fields 135 may be selected from available fields relating to cost, area and volumetric parameters. The fields 137 may be positioned in the document depending on the on-screen positioning thereof.

The merge mapping data structure 137 may allow for the combining of more than one parameter for a particular field 135.

The merge mapping data structure 136 may map other parameters 133, including those relating to preconfigured customer parameters obtained from a customer database, such as name, address parameters and the like.

A merge mapping data structure 136 may be generated for each electronic document template 134.

As such, once the vertices 137 of the interactive perimeter profile configuration control 107 have been configured on-screen in the aforedescribed manner, an on-screen export control may be operated to select an electronic document template 134 and to cause the electronic document generation controller to obtain the associated merge mapping data structure 136 therefor to map the parameters 125, 130 and 133 onto the respective fields 135 as determined by the merge mapping data structure 136 to generate electronic document 137.

The electronic document 137 may be downloaded in PDF format.

The foregoing description, for purposes of explanation, used specific nomenclature to provide a thorough understanding of the invention. However, it will be apparent to one skilled in the art that specific details are not required in order to practise the invention. Thus, the foregoing descriptions of specific embodiments of the invention are presented for purposes of illustration and description. They are not intended to be exhaustive or to limit the invention to the precise forms disclosed as obviously many modifications and variations are possible in view of the above teachings. The embodiments were chosen and described in order to best explain the principles of the invention and its practical applications, thereby enabling others skilled in the art to best utilize the invention and various embodiments with various modifications as are suited to the particular use contemplated. It is intended that the following claims and their equivalents define the scope of the invention.

The term “approximately” or similar as used herein should be construed as being within 10% of the value stated unless otherwise indicated.

1. A computer system comprising a digital display, a graphical user interface controller therefor which displays a graphical user interface, the graphical user interface comprising:
an interactive perimeter profile configuration control comprising vertex controls interactively positionable on screen to define a perimeter of a pool by rays between the vertex controls; and
an interactive depth profile configuration control interactively controllable on screen to define a depth profile of the pool; and
a cost calculation controller which makes cost calculations in accordance with pre-configured size, area and/or volumetric dependent cost calculation parameters and perimeter and the depth profiles configured on-screen.

2. The system as claimed in claim 1, wherein the system automatically calculates size, area and/or volumetric parameters according to the perimeter and the depth profiles configured on-screen.

3. The system as claimed in claim 2, wherein the size, area and/or volumetric parameters comprise at least one of length, width, minimum depth, maximum depth, perimeter length, surface area and interior surface area in accordance with the perimeter of the depth profile.

4. The system as claimed in claim 3, wherein the graphical user interface comprises cost inputs accepting cost according to the at least one of length, width, minimum depth, maximum depth, perimeter length, surface area and interior surface area.

5. The system as claimed in claim 2, wherein the system automatically calculates the size, area and/or volumetric parameters dynamically in real time as the perimeter and the depth profiles are configured on-screen.

6. The system as claimed in claim 1, wherein a graphical user interface comprises view controls to control at least one of position and zoom of a view of the interactive perimeter profile configuration control.

7. The system as claimed in claim 1, wherein the graphical user interface comprises a control for at least one of adding and removing vertex controls.

8. The system as claimed in claim 3, wherein the cost calculation parameters comprise parameters for at least one of the length, width, minimum depth, maximum depth, perimeter length, surface area and interior surface area.

9. The system as claimed in claim 1, wherein the interactive depth profile configuration control displays a vertical cross section of the pool and comprises a plurality of marker controls interactively positionable on-screen thereon, the vertical positioning of the marker controls defining the depth profile.

10. The system as claimed in claim 9, wherein the graphical user interface control determines a length of the pool according to the perimeter and configures the length of the cross-section accordingly.

11. The system as claimed in claim 9, wherein the interactive depth profile configuration control comprises a maximum depth input and wherein the graphical user interface configures the display of the depth of the cross-section accordingly.

12. The system as claimed in claim 9, wherein the depth profile configuration control displays a curved line interpolation between the markers.

13. The system as claimed in claim 9, wherein the depth profile configuration control comprises a control to at least one of add or remove marker controls.

14. The system as claimed in claim 9, wherein each marker displays a respective depth which dynamically updates depending on the vertical position of the marker with respect to the cross-section.

15. The system as claimed in claim 9, further comprising an electronic document generation controller which, for a specified electronic document template comprising a plurality of input fields, obtains a merge mapping data structure associated with the specified electronic document template, and maps parameters from at least one of the perimeter and the depth profiles configured on-screen and the cost calculations to respective input fields of the specified electronic document template as specified by the merge mapping data structure to dynamically generate an electronic document.

16. The system as claimed in claim 15, wherein positioning of the input fields are configurable on screen using the graphical user interface.

17. The system as claimed in claim 15, wherein the merge mapping data structure is configured to map more than one parameter to one input field of the electronic document template.

18. The system as claimed in claim 2, wherein the system calculates a volumetric parameter by summing the product of a perimeter profile width and depth at intervals along a length of the depth profile.

19. The system as claimed in claim 2, wherein the interactive depth profile configuration control is configured for defining a pair of orthogonal depth profiles.

20. The system as claimed in claim 19, wherein the system calculates a volumetric parameter by summing depths of square intervals along both of the pair of orthogonal depth profiles.
